(19) United States
(12) Patent Application Publication
(10) Pub. No.: US 2003/0168939 A1
(43) Pub. Date: Sep. 11, 2003

(54) Device and method of driving piezoelectric actuators for fast switching of wavelengths in a fiber-bragg grating

(76) Inventors: Samad Talebpour, Richmond Hill (CA); Andrew Hudson, Toronto (CA); Jacob Unger, Toronto (CA); Tino Alavie, Thornhill (CA)

Correspondence Address: Ralph A. Dowell, Dowell & Dowell, P.C., Suite 309, 1215 Jefferson Davis Hwy., Arlington, VA, 22202, US

(21) Appl. No.: 10/315,234

(22) Filed: Dec. 10, 2002

Related U.S. Application Data
(60) Provisional application No. 60/337,164, filed on Dec. 10, 2001.

(51) Int. Cl. H01L 41/08

(52) U.S. Cl. 310/328

(57) ABSTRACT

A method to actuate a fiber-Bragg grating (FBG) using piezoelectric actuators is disclosed. In this method, the displacement of the piezoelectric actuator will induce a strain in the FBG, resulting in a shift of the Bragg wavelength (λ_{Bragg}). A suitable application of this device is in optical communications for the controlled switching or filtering of a channel within a specified bandwidth. The piezoelectric actuator is driven by applying effective voltage versus time profiles to the piezoelectric actuator coupled to a fiber Bragg grating to vary strain in the fiber portion containing the grating in order to switch the selected wavelengths of light reflected and/or transmitted by the fiber-Bragg grating. The effective voltage versus time profiles are selected to rapidly change the strain in the selected section of the optical fiber in such a way so as to compensate for effects of creep in the piezoelectric actuator due to the application of voltage thereto and to obtain convergence to a substantially fixed strain in the optical fiber in a pre-selected period of time. This same approach may be used in other applications where on/off type movements are of importance.

### CROSS REFERENCE TO RELATED U.S PATENT APPLICATIONS

This patent application relates to U.S. provisional patent application Serial No. 60/337,164 filed on Dec. 10, 2001 entitled METHOD OF DRIVING PIEZOELECTRIC CERAMICS FOR FAST SWITCHING OF SINGLE OR MULTIPLE BANDWIDTHS OF LIGHT IN A FIBER-BRAGG GRATING

### FIELD OF THE INVENTION

The present invention relates generally to a method of and device for driving piezoelectric actuators to achieve a stable and reproducible displacement within an appropriate time interval for the application. In particular, the present invention relates to a method of, and device for, driving piezoelectric actuators for actuating fiber-Bragg gratings in order to obtain fast switching of wavelength channels in optical communications.

### BACKGROUND OF THE INVENTION

The function of an optical switch using a piezoelectric-actuated fiber-Bragg grating (FBG) shown in FIG. 1c is illustrated in FIGS. 1a and 1b. The characteristics of the unstrained FBG, in this example, will allow for the transmission of wavelengths within the bandwidths of the two channels (Ch 1 and 2) represented by the shaded areas in FIG. 1a; this is termed the “off-state” of the optical switch. Actuation of the FBG by a piezo-electric transducer will displace the reflection spectrum to a longer wavelength (the “on-state” of the optical switch, see FIG. 1b). If an appropriate drive voltage is selected, then the longer wavelength channel (Ch 2) will be reflected by the FBG; this channel can then be separated from the channel located at shorter wavelength (Ch 1). In order to avoid partial switching of the channel, the variation in Bragg wavelength of the FBG must remain sufficiently small, so that the profile of the reflection peak in either strained or unstrained state remains within an amount G (defined as guardband) of the wavelength channel. This means that a fast and accurate displacement of the piezoelectric actuator is required during the switching operation. However, the non-linear response of piezoelectric actuators that give rise to the properties of hysteresis and strain creep in the piezoelectric actuator will cause strain creep in the FBG as well which will limit the performance of the optical switch.

A direct method that has been used to correct for the non-linear response of the piezo involves charge control in the driving circuit. This procedure involves maintaining a steady current to the piezo, and, in practice, is extremely difficult to install successfully because it requires continuous monitoring of the leakage current of the piezo. However, a variation using this methodology where a capacitor is placed in series with the piezoelectric actuator has achieved a fairly good result, but insufficient for telecommunication applications [H. Kaizuka & B. Siu, Japan. J. Appl. Phys., 27, L773].

Methods using closed-loop (active control, see Shiozawa, U.S. Pat. No. 6,046,525) or open-loop (Takada et al., U.S. Pat. No. 5,384,507) operation have been devised to compensate for creep in piezo-actuated devices. Active control requires external measurement of the displacement of the piezo; this provides a feedback signal to stimulate a continuously-variable voltage supply to maintain a constant strain. The displacement could be measured with a strain gauge attached to the piezo or, for the example of actuation of a fiber-Bragg grating, by direct monitoring of the Bragg wavelength, λ_{Bragg}. However, the displacement and optical sensors are costly, particularly if they are required to have fast response times, and, in the former case, there is usually very limited space available for attachment to the piezo. In addition, in order to achieve rapid convergence to a fixed strain, knowledge of the response of the strain to a variable-drive voltage is still needed; otherwise, the strain profile will exhibit large-amplitude oscillations in time.

A constant strain in a piezoelectric actuator can be achieved, without closed-loop operation, by applying pre-determined profiles for the drive voltage that will sufficiently compensate for creep; known as a feed-forward method. A suitable drive-voltage profile can be determined by mathematical modeling of the response of the piezo; the inverse of the operators for hysteresis, vibration and creep will then describe the drive voltage required to achieve a rapid and stable strain response. The development of accurate mathematical models for non-linear response requires substantial computational time, and is not practical for large scale or versatile applications [H. Janocha & K. Kuhnen, Sensors and Actuators, 79, 83 (2000), P. Krejci & K. Kuhnen, IEE Proc.-Control Theory Appl., 148, 185 (2001), D. Croft, G. Shed & S. Devasia, J. Dyn. Systems, Measurement, and Control, 123, 35 (2001)].

A simple method to compensate for material creep of the piezo involves applying a “voltage creep” with a rate equivalent to that observed for the piezo under conditions of constant drive voltage; in this case, a high initial voltage is applied, but, the displacement is maintained at a steady value as the voltage level decays [H. Jung & D. -G. Gweon, Rev. Sci. Inst., 71, 1896 (2000), H. Jung, J. Y. Shim & D. -G. Gweon, Rev. Sci. Inst., 71, 3436 (2000). H. Jung, J. Y. Shim & D. -G. Gweon, Nanotechnology, 12, 14 (2001)]. However, this technique will not correct for the response of the piezo on the very-short time scales required by telecommunication standards for switching. In this case, the sharp onset of the drive voltage can initially result in oscillations in the displacement of the piezo.

The largest difficulty that arises when controlling the displacement of the piezoelectric actuator is the dependence of the strain on the history of applied voltages as well as the time elapsed since the voltage was applied. The use of a FBG to switch a single wavelength band in an optical circuit does not require the same detailed analysis as applications requiring continuously-variable actuation since this procedure involves actuation between discrete off and on states. In this example the displacement of the piezo-electric actuator needs to be controlled accurately between two fixed levels. Therefore, it would be very advantageous to provide a simple electrical-drive circuit to compensate for the time-dependent displacement of the piezoelectric actuator to achieve stable switching.

### SUMMARY OF THE INVENTION

The present invention provides a switching or positioning system for a general device requiring fast actuation that uses piezoelectric actuators. The method uses voltage-time profiles applied to the piezoelectric actuators that give rapid and stable convergence to a selected strain value in the piezoelectric actuator which reduces or eliminates the above-mentioned problem of creep.

In one aspect of the present invention provides a method of switching between selected wavelengths transmitted and/or reflected by a fiber-Bragg grating, comprising;

applying effective voltage versus time profiles to a piezoelectric actuator coupled to a selected section of an optical fiber containing a fiber-Bragg grating to vary strain in the selected section of the optical fiber in order to switch the selected wavelengths of light reflected and/or transmitted by said fiber-Bragg grating, the effective voltage versus time profiles being selected to rapidly change the strain in the selected section of the optical fiber in such a way so as to compensate for effects of creep in the piezoelectric actuator due to the application of voltage thereto and to obtain convergence to a substantially fixed strain in said selected section of the optical fiber in a pre-selected period of time.

In another aspect of the present invention there is provided an optical switch, comprising;

an optical fiber having at least one fiber-Bragg grating in at least one selected section of said fiber;

at least one piezoelectric actuator physically coupled to said at least one selected section of said fiber for applying strain to said at least one selected section of said fiber; and

controller means electrically connected to said at least one piezoelectric actuator for applying effective voltage versus time profiles to said piezoelectric actuator coupled to said selected section of an optical fiber containing a fiber-Bragg grating to vary strain in the selected section of the optical fiber in order to switch the wavelengths of light reflected and/or transmitted by said fiber-Bragg grating, the effective voltage versus time profiles being selected to rapidly change the strain in the selected section of the optical fiber in such away so as to compensate for effects of creep in the piezoelectric actuator due to the application of voltage thereto and to obtain convergence to a substantially fixed strain in said selected section of the optical fiber in a pre-selected period of time.

The present invention also provides a method of rapidly adjusting strain in a piezoelectric actuator which compensates for strain creep, comprising;

applying effective voltage versus time profiles to said piezoelectric actuator, the effective voltage versus time profiles being selected to rapidly change the strain in the piezoelectric actuator in such a way as to compensate for effects of strain creep in the piezoelectric actuator due to the application of voltage thereto and to obtain convergence to a substantially fixed strain in said piezoelectric actuator in a pre-selected period of time.

The present invention also provides a piezoelectric actuator system, comprising;

a piezoelectric actuator; and

controller means electrically connected to said piezoelectric actuator for applying effective voltage versus time profiles to said piezoelectric actuator, the effective voltage versus time profiles being selected to rapidly change the strain in the piezoelectric actuator in such a way as to compensate for effects of strain creep in the piezoelectric actuator due to the application of voltage thereto and to obtain convergence to a substantially fixed strain in said piezoelectric actuator in a pre-selected period of time.

The present invention also provides a positioning system for positioning an object, comprising;

a piezoelectric actuator physically attachable to an object to be positioned al a pre-selected position;

controller means electrically connected to said piezoelectric actuator for applying effective voltage versus time profiles to said piezoelectric actuator for applying strain to said object to move a selected portion of said object, the effective voltage versus time profiles being selected to rapidly change the strain in the piezoelectric actuator in such a way as to compensate for effects of strain creep in the piezoelectric actuator due to the application of voltage thereto and to obtain convergence to a substantially fixed strain in said piezoelectric actuator in a pre-selected period of time.

### BRIEF DESCRIPTION OF THE DRAWINGS

The invention will now be described, by way of non-limiting examples only, reference being had to the accompanying drawings, in which:

FIGS. 1a and 1b are plots of transmission/reflectance versus wavelength showing the function of an ideal optical switch by applying strain to a fiber-Bragg grating using a piezoelectric actuator;

FIG. 1a shows transmission of wavelengths within both channels occurs in the “off state” (without strain applied by the piezoelectric actuator), in this state the reflection profile of the FBG (under the solid line) is separated by an amount G from the bandwidth of both wavelength channels, Ch 1 and 2;

FIG. 1b shows actuation of the FBG by a piezoelectric transducer will displace the reflection spectrum to a region incorporating the longer wavelength channel (termed the “on state”), in this state the transmission profile of the FBG (under the dotted line) is separated by an amount G from the bandwidth of the longer wavelength channel, Ch 2;

FIG. 1c shows an optical fiber with a Bragg grating bonded to a piezoelectric actuator;

FIG. 2 shows an exemplary voltage versus time profile applied to a piezoelectric actuator for actuation of the fiber-Bragg grating; the dashed lines are due to a step voltage and the solid curve is due to a tailored voltage for minimizing creep in accordance with the present invention;

FIG. 3 is a change in wavelength (Δλ) versus time response of the fiber-Bragg grating to the applied voltage shown in FIG. 2, the dashed lines are due to a step voltage and the solid curve is due to a tailored voltage for minimizing creep in accordance with the present invention;

FIG. 4 shows the same voltage versus time profile applied to the piezoelectric actuator, with the reverse polarity appropriate for de-actuation of the fiber-Bragg grating, the dashed lines are due to a step voltage and the solid curve is due to a tailored voltage for minimizing creep in accordance with the present invention; and

FIG. 5 is a change in wavelength (Δλ) versus time response of the fiber-Bragg grating to the applied voltage shown in FIG. 4, the dashed lines are due to a step voltage and the solid curve is due to a tailored voltage for minimizing creep in accordance with the present invention.

### DETAILED DESCRIPTION OF THE INVENTION

As used herein, it will be understood that the terms piezoelectric actuator, piezo, piezoelectric material, piezoelectric transducer, piezoelectric ceramic, hereinafter referred to as piezoelectric actuator, undergoe a strain thereby changing its size when a voltage is applied thereto. When an object is bonded to the piezoelectric actuator it experiences a strain similar to the strain experienced by the strain in the piezoelectric so that as the piezoelectric actuator undergoes elongation, the object undergoes elongation, and as it undergoes contraction, the object bonded to it undergoes contraction.

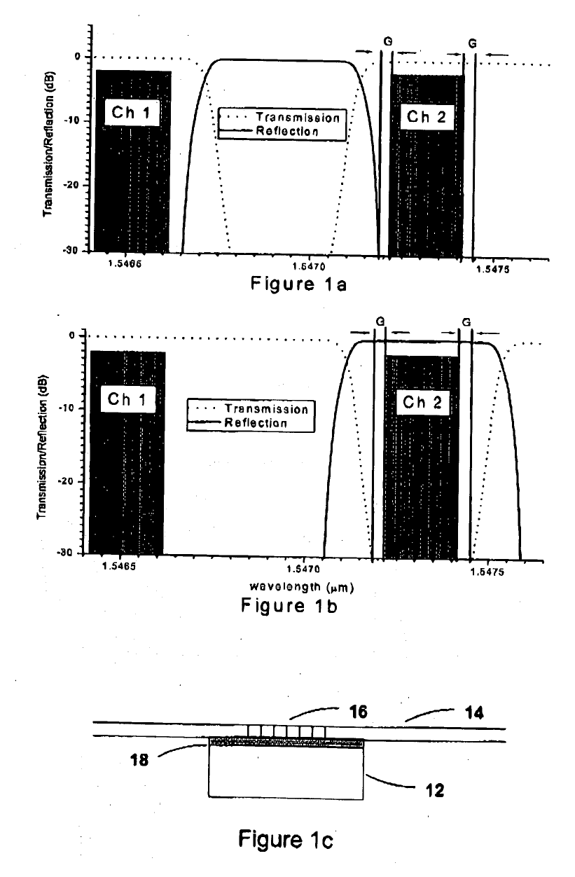

Displacement of a piezoelectric actuator by the application of a potential difference across the piezoelectric can be used to induce a strain on a fiber-Bragg grating (FBG). The resulting shift in the Bragg wavelength, λ_{Bragg}, will allow switching (or filtering) of an optical channel. In the example shown in FIG. 1c, the piezoelectric actuator 12 is needed to provide discrete control of λ_{Bragg} in the Bragg grating 16 for light propagating through the fiber 14 (bonded to actuator 12 using a bonding agent 18) between two wavelength channels (containing two Bragg center-wavelength values). A method to induce a rapid displacement of the piezoelectric actuator 12 to strain the FBG thereby switching between these discrete wavelength channels is required for fast switching between optical channels. In addition, a method of compensating for creep inherently present in the piezoelectric actuator 12 (due to application of a step voltage) and which is transferred to the section of the optical fiber physically bonded to the piezoelectric actuator is needed to maintain a stable signal after switching. A method for compensating for creep in accordance with the present invention is described and demonstrated hereinafter by applying a pre-selected voltage-time profile tailored to the piezoelectric actuator 12 to drive the FBG between different strain states in order to provide the switching between optical channels.

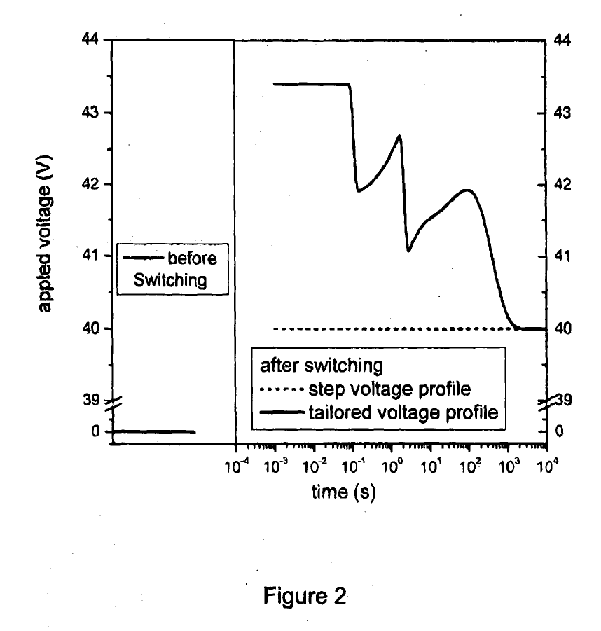

The method forming the present invention for rapid switching of an optical switch involves applying an effective series of superimposed voltage pulses to drive the piezoelectric actuator 12. In the typical operation of a piezoelectric actuator one applies an initial large step voltage. The effect of long-term drift in the Bragg wavelength, λ_{Bragg}, caused by variation in the strain in the FBG due to strain creep in the piezoelectric actuator due to the step voltage can be reduced by applying an additional smaller voltage pulse above the step voltage to stimulate rapid displacement of the piezoelectric actuator 12. If the magnitude of the voltage pulse is then allowed to decay to the step voltage, the strain will converge to a near-constant value. Furthermore, the rapid displacement of the piezoelectric actuator 12 enables a very fast switching between strain values in the FBG resulting in a change in the wavelength channels being transmitted and/or reflected. The magnitude of the voltage pulse and its decay constant must be optimized to achieve the required strain. However, by itself, this combination of the initial large step voltage and the smaller voltage pulse will not result in a sufficiently rapid convergence of the peak position of the reflection bandwidth of the FBG. In particular, the response of the piezoelectric actuator 12 to a rapid change in the applied voltage leads to the Bragg wavelength of the FBG overshooting the target level. This will lead to unstable switching of λ_{Bragg} in the short term. However, the inventors have discovered that a further number of delayed inverse-voltage pulses in combination with the smaller voltage pulse described above superimposed on the step voltage will assist in a more rapid convergence to a fixed value of strain; an example of which is illustrated in FIG. 2.

More particularly, stable and rapid switching is achieved by applying to the piezoelectric actuator voltage versus time profiles which include a step voltage and a series of voltage pulses superimposed on the step voltage to compensate for creep due to the step voltage. The series of voltage pulses includes a first voltage pulse with the same polarity as the step voltage and is sufficiently large to stimulate rapid displacement of the piezoelectric actuator 12 to reach a substantially fixed strain value, with subsequent voltage pulses in the series of voltage pulses being of opposite polarity and lower magnitude than the first voltage pulse so that the strain remains within a selected tolerance from fixed strain value until the convergence to the fixed strain is obtained.

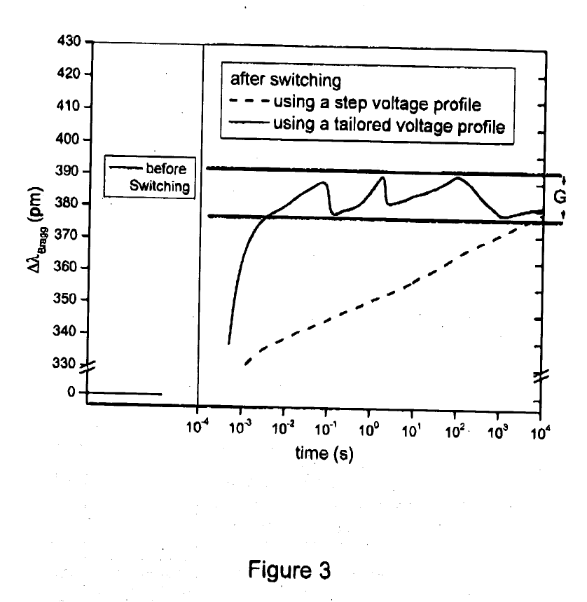

Selection of appropriate parameters for the drive voltage profile will enable accurate switching of the optical channels within a specified tolerance. The resulting time dependent profile for the λ_{Bragg}, is maintained within a narrow window of wavelength values (G) for the measured time interval (see FIG. 3). This should be compared to the result obtained when a simple step voltage function (see dotted line in FIG. 2) is applied to the piezoelectric actuator 12. The resulting profile for λ_{Bragg} shows substantial drift without converging to a fixed wavelength (see dotted line in FIG. 3).

In this invention, the piezoelectric actuator 12 was initially supplied with a voltage in excess of the step value shown as a dotted line in FIG. 2. This additional voltage was then allowed to decay exponentially to the step value. In order to avoid the λ_{Bragg} from overshooting the required level, at an appropriate time that was determined experimentally, a negative voltage pulse was superimposed on the voltage-time profile. This last step needed to be repeated a second time in order to maintain the λ_{Bragg} within the required band. In both cases, the onsets, time constants and magnitudes of the negative voltage pulses were determined experimentally. In the example illustrated in FIGS. 2 and 3, the piezoelectric actuator 12 was driven by the voltage profile described approximately by the equation;

V(Volts)=40.0+3.4exp(−t/1333.0s)−1.6θ(t−0.1s)exp(−(t−0.1s)/2.0s)−2.0θ(t−2.0s)exp(−(t−2.0s)/86.0s)

as shown in FIG. 2,

n.b. θ(x)=0 if x<0, θ(x)=1 if x≧0, the onset time for the initial step voltage of 40V was ˜2 ms.

The parameters for the drive voltage profile were optimized in order to achieve, after 5 ms of the onset of the switch, a shift in λ_{Bragg} to a wavelength stable within the guardband G (see FIG. 3) of bandwidth 15 pm for the measured time interval.

The reverse of this procedure must be applied with the opposite polarity waveform to close the optical switch and allow transmission of the wavelengths within the channel; i.e.

V(Volts)=−3.4 exp(−t/333.0s)+1.6θ(t−0.1s)exp(−(t−0.1s)/2.0s)+2.0 θ(t−2.0s)exp(−(t−2.0s)/86.0s)

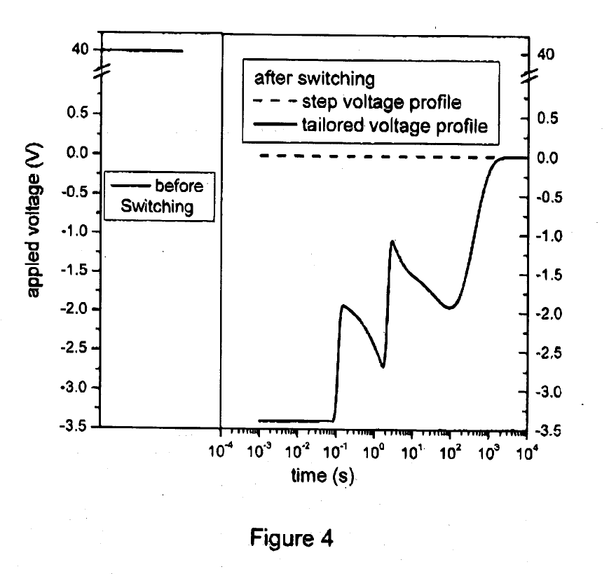

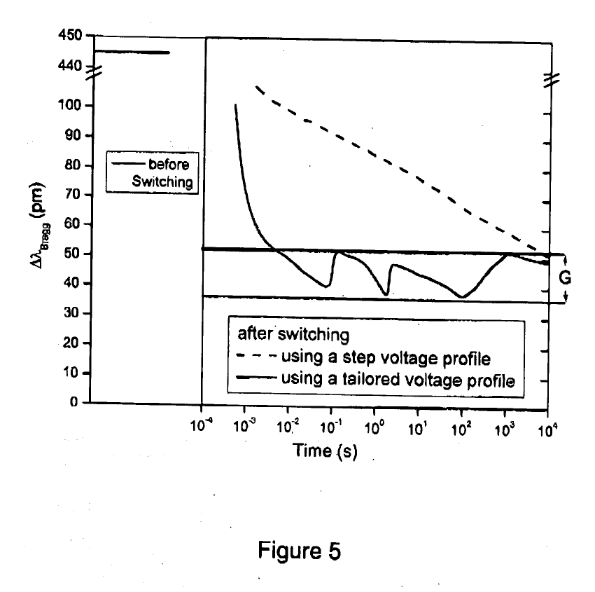

as shown in the drive-voltage profile in FIG. 4 and displacement characteristics of the piezoelectric actuator are illustrated in FIG. 5. As before, the λ_{Bragg} is maintained within the 15 pm gardband G after 5 ms of the onset of the drive voltage.

The effect of applying the series of superimposed voltage pulses is to achieve a rapid displacement of the piezoelectric actuator 12 thus imparting strain to the FBG, and stabilization within a narrow range of values for strain corresponding to Bragg wavelengths within the gardband G (see FIGS. 3 and 5). In the absence of these features in the drive voltage, the piezoelectric actuator 12 was seen to undergo strain creep continuously during its lifetime, in this case the λ_{Bragg} will follow an approximate equation;

Δλ_{Bragg}=Δλ_{Bragg}(t=0.1s)(1±γlog₁₀(t(s)/0.1s))

where γ is the creep factor. This behavior is shown by the dotted lines in FIGS. 3 and 5.

It rill be understood that while the present invention has been described with respect to switching the Bragg wavelengths of fiber-Bragg gratings, it will be understood that the present invention may be used as a switching or positioning system for a general device requiring fast actuation. Previous approaches for compensation of creep using feedback methods [Shiozawa] have resulted in convergence to a constant strain after a short time delay, but they have failed to achieve very fast actuation. The application of a pre-determined (time-dependent) voltage enables the response of the piezoelectric actuator to be modified to obtain the required strain after a specified time interval. The development of accurate mathematical models for the non-linear response of the piezoelectric actuator to determine an appropriate drive-voltage profile is very time consuming. Very surprisingly, the new method disclosed herein of using a series of voltage pulses can be easily applied to a device requiring fast actuation by a piezoelectric actuator. In this case, a voltage profile is tailored to the device by experimentally varying a small number of parameters. These were selected for the above example of actuation of a fiber-Bragg grating to achieve a strain within a tolerance of 15 pm for a switching speed of 5 ms. However, it will be appreciated that a different tolerance for strain values and switching speed could be achieved by selecting appropriately different parameters.

Initially, this procedure should be set up to allow for active adjustment of the parameters describing the sequence of voltage pulses. These values should then be tuned to achieve the desired tolerance for the strain values and switching speed. These can then be programmed into the drive-voltage circuit and applied for subsequent actuation of the piezoelectric actuator.

The parameters for a different switching or positioning system using any type of piezoelectric-ceramic material can be modified according to the requirements for that system. In the above example, the sequencing and parameters describing each pulse were selected to achieve the required strain on a FBG to switch the reflection wavelengths between two different regions, within a certain tolerance for the bandwidth and switching speed. However, the profile for the drive voltage can be tailored to the requirements of positioning tolerance and speed for any system. Examples of other positioning systems include Scanning Tunneling Microscopy, Atomic Force Microscopy, tunable laser cavities, positioning of optical components, positioning of microscopes, just to mention a few applications. It will also be the case that there exist many different voltage sequences and pulse characteristics that achieve the same result. The structure for each voltage pulse need not be restricted to exponential decay (as in the example given above); they can be described by an unlimited number of different functional forms.

In addition, the profile for the sequence of pulses need not be a continuous variable voltage as described above. It might also be described by a discrete number of voltage steps, or the voltage profile can be generated from a digital encoded signal through a digital-to-analog converter.

This sequence of voltage pulses described above was designed to maintain the piezo-induced strain within-a certain tolerance for a measured time interval of 10⁴ s. It would be possible to achieve a stable strain for a much longer (or indefinite) time period by modifying the magnitude, shape or application time of the sequence of pulses. Alternatively, the drive voltage profile ran be adjusted in a series of steps at suitable intervals in time. For this procedure, the initially-applied voltage would need to be sufficient to achieve the required strain within a specified switching speed, and the time intervals and magnitude of the subsequently applied voltage steps must be sufficient to maintain the strain within an appropriate tolerance. The stepwise adjustments to the applied voltage will need to be applied for a much longer period of time than the sequence of pulses shown in FIGS. 2 and 4; however, the interval between each step in the applied voltage will increase by approximately one order of magnitude each time. For the example responses of the fiber-Bragg grating shown above in FIGS. 3 and 5, an appropriate voltage-time profile scheme to achieve the same performance for a longer time period will be described by the equations;

$$\begin{matrix}{V}_{on} ( Volts ) = 40.0 + {V}_{correction} - {\sum }_{n = 0}^{N} {V}_{n} θ ( t - {τ}_{n} ) \\ {V}_{off} ( Volts ) = 0 - {V}_{correction} + {\sum }_{n = 0}^{N} {V}_{n} θ ( t - {τ}_{n} ) \end{matrix}$$

where V_{correction} is the necessary voltage that must be applied (in addition to the step value; in this case, 40.0V) to achieve the required strain at t—5 ms, and N is fixed by the condition,

$${\sum }_{n = 0}^{n = N} {V}_{n} = {V}_{correction}$$

The quantities Vₙ and τₙ are interdependent and are chosen such that for t>5 ms, the strain remains within the required tolerance. As before, this scheme could be adapted for other applications and there exist an unlimited number of different functional forms for the applied voltage that will achieve the same result by modifying the voltage at a series of appropriate time intervals.

The method of the present invention has been described for applications requiring on/off-type switching or positioning movements. However, it will be understood that this method can be applied to switch between any number of discrete states. In this case, there would exist a matrix of parameters to describe the series of pulses or stepwise changes in the applied voltage to compensate for piezo-induced creep in the transitions between any pair of states. As before, either each voltage pulse will have an appropriate functional form or each stepwise change in voltage will have an appropriate time interval to achieve the required tolerance for switching time and positioning accuracy, and the necessary parameters will be recalled when a particular transition is selected.

As used herein, the terms “comprises”, “comprising”, “including” and “includes” are to be construed as being inclusive and open ended, and not exclusive. Specifically, when used in this specification including claims, the terms “comprises”, “comprising”, “including” and “includes” and variations thereof mean the specified features, steps or components are included. These terms are not to be interpreted to exclude the presence of other features, steps or components.

The foregoing description of the preferred embodiments of the invention has been presented to illustrate the principles of the invention and not to limit the invention to the particular embodiment illustrated. It is intended that the scope of the invention be defined by all of the embodiments encompassed within the following claims and their equivalents.

### REFERENCES

U.S. Pat. No. 5,384,507 (January 1995) Takada et al. METHOD OF AND DEVICE FOR DRIVING PIEZO-ELECTRIC ELEMENTS AND SYSTEM FOR CONTROLLING MICROMOTION MECHANISM

U.S. Pat. No. 6,046,525 March 1997 Shiozawa PIEZO-ELECTRIC ACTUATOR CONTROL METHOD AND DEVICE AND VARIABLE WAVELENGTH FILTER USING THE PIEZO-ELECTRIC DEVICE

H. Kaizuka & B. Siu, Japan. J. Appl. Phys., 27, L773.

H. Janocha & K. Kuhnen, Sensors and Actuators, 79, 83 (2000).

P. Krejci & K. Kuhnen, IEE Proc. Control Theory Appl., 148, 185 (2001).

D. Croft, G. Shed & S. Devasia, J. Dyn. Systems, Measurement, and Control, 123, 35 (2001)]

H. Jung & D. -G. Gweon, Rev. Sci. Inst., 71, 1896 (2000).

H. Jung, J. Y. Shim & D. -G. Gweon, Rev. Sci. Inst., 71, 3436 (2000).

H. Jung, J. Y. Shim & D. -G. Gweon, Nanotechnology, 12, 14 (2001).

Therefore what is claimed is:

1. A method of switching between selected wavelengths transmitted and/or reflected by a fiber-Bragg grating, comprising;
applying effective voltage versus time profiles to a piezoelectric actuator coupled to a selected section of an optical fiber containing a fiber-Bragg grating to vary strain in the selected section of the optical fiber in order to switch the selected wavelengths of light reflected and/or transmitted by said fiber-Bragg grating, the effective voltage versus time profiles being selected to rapidly change the strain in the selected section of the optical fiber in such a way so as to compensate for effects of creep in the piezoelectrc actuator due to the application of voltage thereto and to obtain convergence to a substantially fixed strain in said selected section of the optical fiber in a pre-selected period of time.

2. The method according to claim 1 wherein said effective voltage versus time profiles include a step voltage and a series of voltage pulses superimposed on the step voltage to compensate for creep due to the step voltage, the series of voltage pulses including a first voltage pulse with the same polarity as said step voltage and being sufficiently large to stimulate rapid displacement of the piezoelectric element to reach said substantially fixed strain, and wherein subsequent voltage pulses in the series of voltage pulses are of opposite polarity and lower magnitude than the first voltage pulse so that the strain remains within a selected tolerance from said substantially fixed strain until the convergence to said substantially fixed strain is obtained.

3. The method according to claim 2 wherein said voltage pulses are exponentially decaying voltage pulses.

4. The method according to claim 2 wherein said voltage pulses are stepwise transitions in voltage.

5. The method according to claim 2 wherein said pre-selected period time less than about 5 milliseconds.

6. The method according to claim 2 wherein said effective voltage versus time profiles are selected to give said rapid switching with pre-selected switching times.

7. The method according to claim 1 wherein said selected wavelengths are telecommunication wavelengths, and wherein the fast switching is suitable to ensure that an optical link is not interrupted for an unsuitable long time for telecommunication.

8. The method according to claim 2 wherein one of said selected wavelengths is a first Bragg wavelength λ_{Bragg1} and a second of said selected wavelengths is a second Bragg wavelength λ_{Bragg2}.

9. An optical switch, comprising;
an optical fiber having at least one fiber-Bragg grating in at least one selected section of said fiber;
at least one piezoelectric actuator physically coupled to said at least one selected section of said fiber for applying strain to said at least one selected section of said fiber; and
controller means electrically connected to said at least one piezoelectric actuator for applying effective voltage versus time profiles to said piezoelectric actuator coupled to said selected section of an optical fiber containing a fiber-Bragg grating to vary strain in the selected section of the optical fiber in order to switch the wavelengths of light reflected and/or transmitted by said fiber-Bragg grating, the effective voltage versus time profiles being selected to rapidly change the strain in the selected section of the optical fiber in such a way so as to compensate for effects of creep in the piezoelectric actuator due to the application of voltage thereto and to obtain convergence to a substantially fixed strain in said selected section of the optical fiber in a pre-selected period of time.

10. The optical switch according to claim 9 wherein said effective voltage versus time profiles include a step voltage and a series of voltage pulses superimposed on the step voltage to compensate for creep due to the step voltage, the series of voltage pulses including a first voltage pulse with the same polarity as said step voltage and being sufficiently large to stimulate rapid displacement of the piezoelectric element to reach said substantially fixed strain, and wherein subsequent voltage pulses in the series of voltage pulses are of opposite polarity and lower magnitude than the first voltage pulse so that the strain remains within a selected tolerance from said substantially fixed strain until the convergence to said substantially fixed strain is obtained.

11. The optical switch according to claim 10 wherein said voltage pulses are exponentially decaying voltage pulses.

12. The optical switch according to claim 10 wherein said voltage pulses are stepwise transitions in voltage.

13. The optical switch according to claim 10 wherein said pre-selected period time less than about 5 milliseconds.

14. The optical switch according to claim 10 wherein said effective voltage versus time profiles are selected to give said rapid switching with pre-selected switching times.

15. The optical switch according to claim 9 wherein said selected wavelengths are telecommunication wavelengths, wherein said optical switch is a component in a telecommunication network and wherein the switching is sufficiently fast to ensure that an optical link in said network is not interrupted for unsuitable long times.

16. The optical switch according to claim 9 wherein one of said selected wavelengths is a first Bragg wavelength λ_{Bragg1} and a second of said selected wavelengths is a second Bragg wavelength λ_{Bragg2}.

17. A method of rapidly adjusting strain in a piezoelectric actuator which compensates for strain creep, comprising;
applying effective voltage versus time profiles to said piezoelectric actuator, the effective voltage versus time profiles being selected to rapidly change the strain in the piezoelectric actuator in such a way as to compensate for effects of strain creep in the piezoelectric actuator due to the application of voltage thereto and to obtain convergence to a substantially fixed strain in said piezoelectric actuator in a pre-selected period of time.

18. The method according to claim 17 wherein said effective voltage versus time profiles include a step voltage and a series of voltage pulses superimposed on the step voltage to compensate for creep due to the step voltage, the series of voltage pulses including a first voltage pulse with the same polarity as said step voltage and being sufficiently large to stimulate rapid displacement of the piezoelectric element to reach said substantially fixed strain, and wherein subsequent voltage pulses in the series of voltage pulses are of opposite polarity and lower magnitude than the first voltage pulse so that the strain remains within a selected tolerance from said substantially fixed strain until the convergence to said substantially fixed strain is obtained.

19. The method according to claim 18 wherein said voltage pulses are exponentially decaying voltage pulses.

20. The method according to claim 18 wherein said voltage pulses are stepwise transitions in voltage.

21. A piezoelectric actuator system, comprising;
a piezoelectric actuator; and
controller means electrically connected to said piezoelectric actuator for applying effective voltage versus time profiles to said piezoelectric actuator, the effective voltage versus time profiles being selected to rapidly change the strain in the piezoelectric actuator in such a way as to compensate for effects of strain creep in the piezoelectric actuator due to the application of voltage thereto and to obtain convergence to a substantially fixed strain in said piezoelectric actuator in a pre-selected period of time.

22. The piezoelectric actuator system according to claim 21 wherein said effective voltage versus time profiles include a step voltage and a series of voltage pulses superimposed on the step voltage to compensate for strain creep due to the step voltage, the series of voltage pulses including a first voltage pulse with the same polarity as said step voltage and being sufficiently large to stimulate rapid displacement of the piezoelectric element to reach said substantially fixed strain, and wherein subsequent voltage pulses in the series of voltage pulses are of opposite polarity and lower magnitude than the first voltage pulse so that the strain remains within a selected tolerance from said substantially fixed strain until the convergence to said substantially fixed strain is obtained.

23. The piezoelectric actuator system according to claim 22 wherein said voltage pulses are exponentially decaying voltage pulses.

24. The piezoelectric actuator system according to claim 22 wherein said voltage pulses are stepwise transitions in voltage.

25. A positioning system for positioning an object, comprising;
a piezoelectric actuator physically attachable to an object to be positioned at a pre-selected position;
controller means electrically connected to said piezoelectric actuator for applying effective voltage versus time profiles to said piezoelectric actuator for applying strain to said object to move a selected portion of said object, the effective voltage versus time profiles being selected to rapidly change the strain in the piezoelectric actuator in such a way as to compensate for effects of strain creep in the piezoelectrc actuator due to the application of voltage thereto and to obtain convergence to a substantially fixed strain in said piezoelectric actuator in a pre-selected period of time.

26. The positioning system according to claim 25 wherein said effective voltage versus time profiles include a step voltage and a series of voltage pulses superimposed on the step voltage to compensate for strain creep due to the step voltage, the series of voltage pulses including a first voltage pulse with the same polarity as said step voltage and being sufficiently large to stimulate rapid displacement of the piezoelectric element to reach said substantially fixed strain, and wherein subsequent voltage pulses in the series of voltage pulses are of opposite polarity and lower magnitude than the first voltage pulse so that the strain remains within a selected tolerance from said substantially fixed strain until the convergence to said substantially fixed strain is obtained.

27. The positioning system according to claim 26 wherein said voltage pulses are exponentially decaying voltage pulses.

28. The positioning system according to claim 26 wherein said voltage pulses are stepwise transitions in voltage.
